(19) United States
(12) Patent Application Publication
(10) Pub. No.: US 2014/0240892 A1
(43) Pub. Date: Aug. 28, 2014

(54) ELECTROSTATIC CHUCK, RETICLE, AND ELECTROSTATIC CHUCK METHOD

(71) Applicant: Kabushiki Kaisha Toshiba, Minato-ku (JP)

(72) Inventors: Yosuke OKAMOTO, Tokyo (JP); Nobuhiro KOMINE, Aichi-ken (JP)

(73) Assignee: Kabushiki Kaisha Toshiba, Minato-ku (JP)

(21) Appl. No.: 13/948,316

(22) Filed: Jul. 23, 2013

(30) Foreign Application Priority Data
Feb. 28, 2013 (JP) 2013-038926

(51) Int. Cl. H01L 21/683

(52) U.S. Cl. CPC H01L 21/6833
USPC 361/234; 359/265

(57) ABSTRACT

According to one embodiment, an electrostatic chuck is capable of holding a reticle by electrostatic attraction force. The reticle has a planar external shape of a rectangle or a square. The electrostatic chuck includes: a first attraction unit capable of attracting the reticle by the electrostatic attraction force; and a substrate supporting the first attraction unit. The first attraction unit is symmetrical with respect to a first line when the reticle is attracted to the first attraction unit. The first line crosses two opposing sides of the rectangle or the square.

### CROSS-REFERENCE TO RELATED APPLICATIONS

This application is based upon and claims the benefit of priority from Japanese Patent Application No. 2013-038926, filed on Feb. 28, 2013; the entire contents of which are incorporated herein by reference.

### FIELD

Embodiments described herein relate generally to a electrostatic chuck, a reticle, and a electrostatic chuck method.

### BACKGROUND

In an EUV (extreme ultraviolet) exposure apparatus, in general, the entire back surface of a reticle is electrostatically attracted and the front surface side of the reticle is irradiated with light, and the light reflected at the front surface is applied to a substrate to perform exposure operation. When the entire back surface of the reticle is attracted to the electrostatic chuck, the reticle may be influenced by the degree of flatness of the electrostatic chuck, contaminants remaining between the reticle and the electrostatic chuck, etc., and the reticle itself may be intricately warped. As a result, misregistration between a pattern provided on the reticle and a pattern of the objective may occur. If the reticle itself is intricately warped, it is difficult to correct the misregistration by optical approximation.

In a semiconductor manufacturing process using the EUV exposure apparatus, a pattern is formed by light exposure on mark that has been formed in a preprocess, while making alignment with the mark. At this time, the misregistration between an upper layer and a lower layer will cause an electrical short circuit and an open defect to lead to a yield reduction. Hence, high registration accuracy is required. Thus, an electrostatic chuck is desired that can attract a reticle while suppressing the intricate warp of the reticle.

### BRIEF DESCRIPTION OF THE DRAWINGS

FIG. 1A is a schematic stereo view of an electrostatic chuck according to a first embodiment, FIG. 1B is a schematic plan view of the electrostatic chuck according to the first embodiment, and FIG. 1C is a schematic cross-sectional view in the position of line A-A′ of FIG. 1B;

FIG. 2A to FIG. 3 are schematic views showing a light exposure method according to the first embodiment;

FIG. 4A is a schematic stereo view of an electrostatic chuck according to a first modification example, and FIG. 4B is a schematic cross-sectional view in the position of line A-A′ of FIG. 4A;

FIG. 5A is a schematic stereo view of an electrostatic chuck according to a second modification example, FIG. 5B is a schematic plan view of a reticle attracted to the electrostatic chuck according to the second modification example, and FIG. 5C is a schematic stereo view of the reticle attracted to the electrostatic chuck according to the second modification example;

FIG. 6A is a schematic stereo view of an electrostatic chuck according to a third modification example, and FIG. 6B is a schematic cross-sectional view in the position of line A-A′ of FIG. 6A;

FIG. 7A is a schematic stereo view of an electrostatic chuck according to a reference example, and FIG. 7B is a schematic cross-sectional view in the position of line A-A′ of FIG. 7A;

FIG. 8A is a schematic diagram showing shifts of a pattern according to the reference example, and FIG. 8B is a schematic diagram showing a state after the shifts of the pattern according to the reference example are amended by correction; and

FIG. 9A is a schematic diagram showing shifts of a pattern according to the embodiment, and FIG. 9B is a schematic diagram showing a state after the shifts of the pattern according to the embodiment are amended by correction.

### DETAILED DESCRIPTION

In general, according to one embodiment, an electrostatic chuck is capable of holding a reticle by electrostatic attraction force. The reticle has a planar external shape of a rectangle or a square. The electrostatic chuck includes: a first attraction unit capable of attracting the reticle by the electrostatic attraction force; and a substrate supporting the first attraction unit. The first attraction unit is symmetrical with respect to a first line when the reticle is attracted to the first attraction unit. The first line crosses two opposing sides of the rectangle or the square.

Hereinbelow, embodiments are described with reference to the drawings. In the following description, identical components are marked with the same reference numerals, and a description of components once described is omitted as appropriate.

### First Embodiment

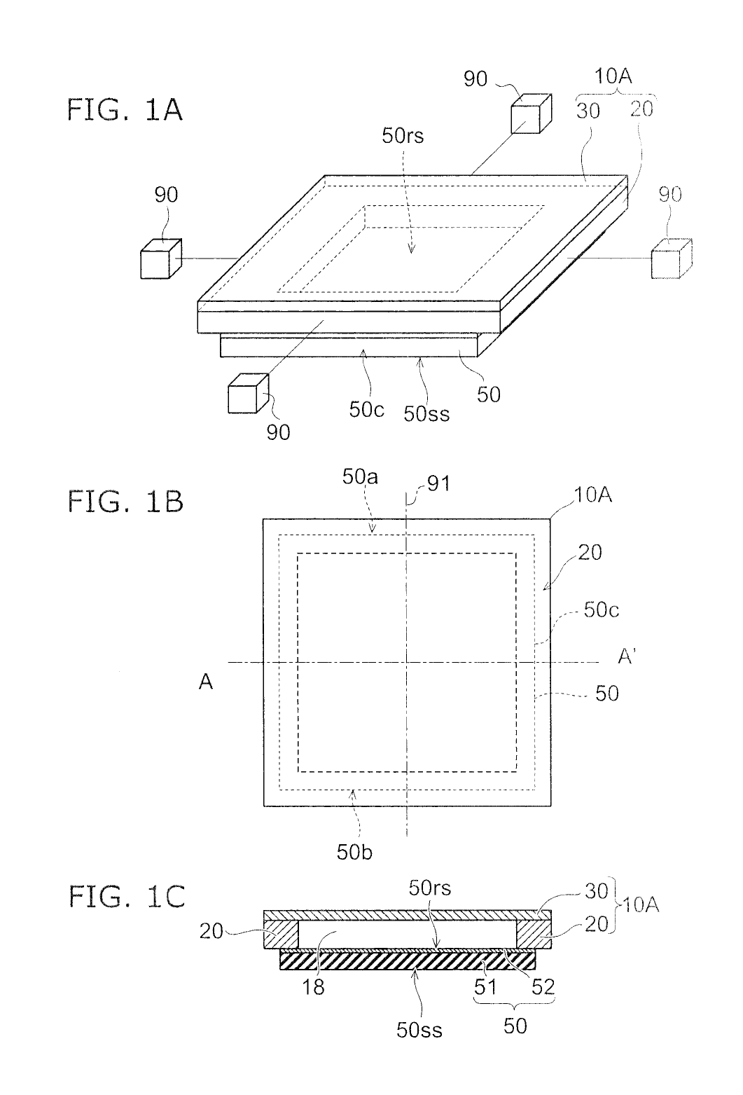

FIG. 1A is a schematic stereo view of an electrostatic chuck according to a first embodiment, FIG. 1B is a schematic plan view of the electrostatic chuck according to the first embodiment, and FIG. 1C is a schematic cross-sectional view in the position of line A-A′ of FIG. 1B.

FIG. 1A and FIG. 1B show an electrostatic chuck 10A and also a reticle (photomask) 50 attracted to the electrostatic chuck 10A. In addition, an optical sensor 90 that detects the position of the electrostatic chuck 10A is shown. The reticle 50 has a front surface 50ss and a back surface 50rs on the opposite side to the front surface 50ss. The planar external shapes of the front surface 50ss and the back surface 50rs of the reticle 50 include a rectangle or a square. In the embodiment, the reticle 50 of which the planar external shape is a square is shown as an example.

The electrostatic chuck 10A can hold the reticle 50 by electrostatic attraction force. The electrostatic chuck 10A includes an attraction unit 20 (a first attraction unit) capable of attracting the reticle 50 by electrostatic attraction force and a substrate 30 supporting the attraction unit 20.

In a state where (or when) the reticle 50 is attracted to the attraction unit 20, the attraction unit 20 is symmetrical with respect to a first line (for example, a center line 91 shown in FIG. 1B) crossing two opposing sides 50a and 50b of the rectangle or the square of the reticle 50. For example, the attraction unit 20 is in a loop shape, and the attraction unit 20 is located on the outer edge 50c of the reticle 50. The attraction unit 20 is symmetrical with respect to the center line 91.

In the state where the reticle 50 is attracted to the attraction unit 20, a space 18 is formed between the reticle 50 and the electrostatic chuck 10A. The center line 91 shown in FIG. 1B is not limited to a center line dividing the rectangle or the square into two equal parts. The center line 91 may be slightly shifted in the lateral direction of FIG. 1B, or may be slightly rotated around the center of the center line 91.

The material of the attraction unit 20 contains, for example, a ceramic, glass, or the like. An electrode (not shown) that generates electrostatic force is provided in the attraction unit 20. A cooling water path etc. may be provided in the attraction unit 20 with consideration of the heat generation of the attraction unit 20. The material of the substrate 30 is appropriately selected from, for example, a ceramic, glass, a resin, stainless steel, aluminum, and the like.

The reticle 50 includes an insulating body 51 and a conductive layer 52. The material of the insulating body 51 contains, for example, quartz, glass, or the like. The conductive layer 52 contains, for example, chromium (Cr). In the reticle 50, a fine pattern is provided on the front surface 50ss side. The conductive layer 52 for electrostatic attraction is provided on the back surface 50rs side of the reticle 50.

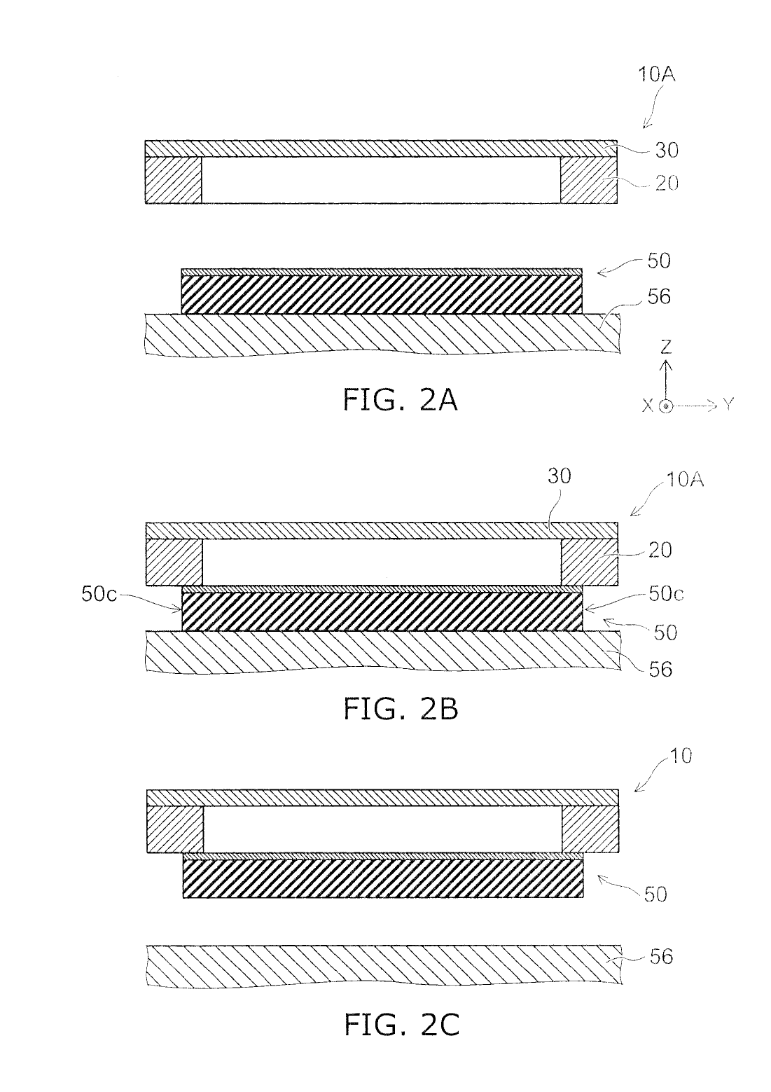

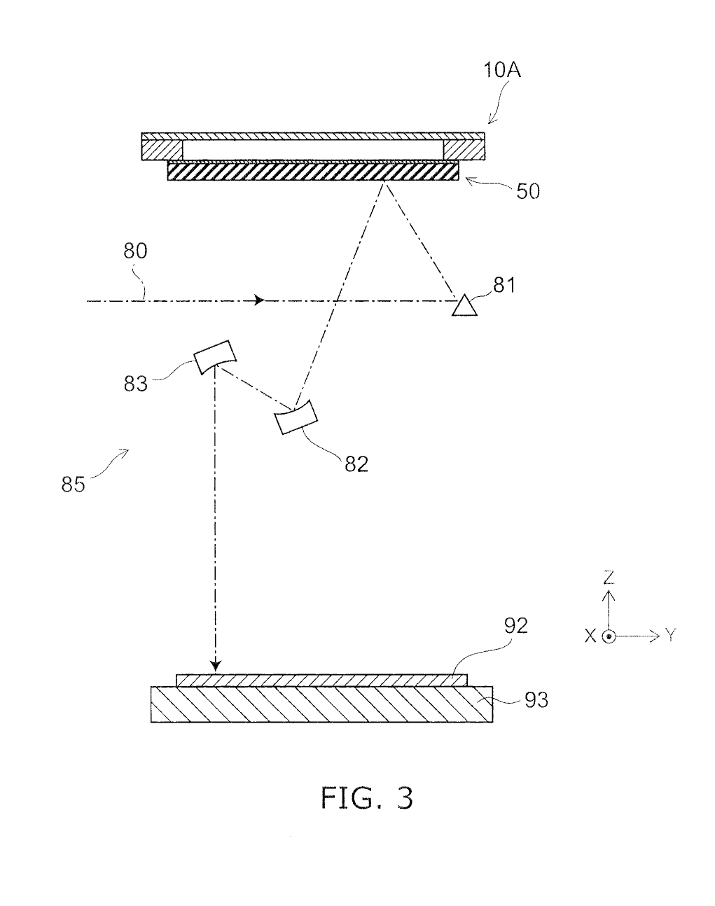

FIG. 2A to FIG. 3 are schematic views showing a light exposure method according to the first embodiment.

First, as shown in FIG. 2A, the reticle 50 is placed on a stage 56. The electrostatic chuck 10A is disposed above the reticle 50. The electrostatic chuck 10A is supported by, for example, a transfer arm (not shown).

Next, as shown in FIG. 2B, the electrostatic chuck 10A is mounted on the reticle 50. For example, a prescribed voltage is applied to the electrode provided in the attraction unit 20, and the reticle 50 is attracted to the attraction unit 20 of the electrostatic chuck 10A. By such a method, the reticle 50 is attracted to the attraction unit 20 of the electrostatic chuck 10A. The attraction unit 20 is located on the outer edge 50c of the reticle 50.

Next, as shown in FIG. 2C, the reticle 50 is lifted by the electrostatic chuck 10A to be separated from the stage 56. In the drawing, an XYZ coordinate system is introduced. The two-dimensional plane formed by the X-axis and the Y-axis is the horizontal plane with respect to the ground, the +Z direction is the anti-gravity direction, and the −Z direction is the gravity direction. The reticle 50 separated from the stage 56 is, for example, disposed in an optical system by the transfer arm. FIG. 3 shows this state.

As shown in FIG. 3, the reticle 50 is disposed above a semiconductor wafer 92. The semiconductor wafer 92 is placed on a wafer stage 93. The electrostatic chuck 10A and the wafer stage 93 can move in the X direction, the Y direction, and the Z direction.

With the progress of miniaturization of pattern formation in recent years, EUV light 80 is used as exposure light. An optical system 85 employs a reflection optical system in a vacuum in view of the characteristics of the EUV light 80. Thus, the electrostatic chuck 10A has a structure that electrically attracts the back surface of the reticle 50.

An alignment mechanism measures the coordinates of a mark that has been formed in a preprocess and determines the coordinates of the shot of light exposure. Also the misregistration in the shot is approximated to a polynomial similarly to conventional exposure apparatuses, and a mechanism that alters the shape of an optical component (e.g. a mirror) to make correction is employed.

The EUV light 80 is reflected by an optical component 81, and is incident on the pattern formation surface side of the reticle 50. The EUV light 80 reflected by the pattern formation surface side of the reticle 50 is reflected by an optical component 82, and is further reflected by an optical component 83. Then, the EUV light 80 reaches the semiconductor wafer 92 and light exposure is performed. Thereby, the exposure light reflected at the reticle 50 is transferred onto the semiconductor wafer 92. Before effects of the embodiment are described, modification examples of the first embodiment are described.

### FIRST MODIFICATION EXAMPLE

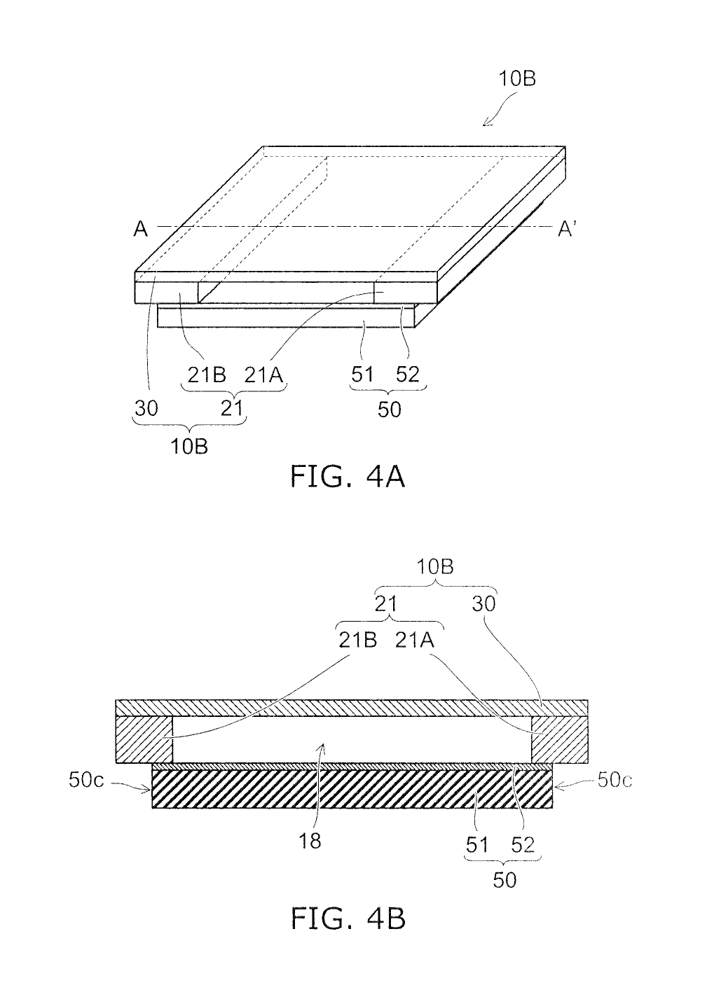

FIG. 4A is a schematic stereo view of an electrostatic chuck according to a first modification example, and FIG. 4B is a schematic cross-sectional view in the position of line A-A′ of FIG. 4A.

FIG. 4A and FIG. 4B show an electrostatic chuck 105 and also the reticle 50 attracted to the electrostatic chuck 10B.

An attraction unit 21 of the electrostatic chuck 10B according to the first modification example includes a first support unit (a first attraction region) 21A and a second support unit (a second attraction region) 21B. In a state where the reticle 50 is attracted to the attraction unit 21, the first support unit 21A and the second support unit 21B are located individually on opposing outer edges 50c of the reticle 50. In other words, each of the first support unit 21A and the second support unit 21B is located on any of opposing outer edges 50c of the reticle 50. That is, both ends of the reticle 50 are attracted by the electrostatic chuck 10B. In the state where the reticle 50 is attracted to the attraction unit 21, a space 18 is formed between the reticle 50 and the electrostatic chuck 10B.

### SECOND MODIFICATION EXAMPLE

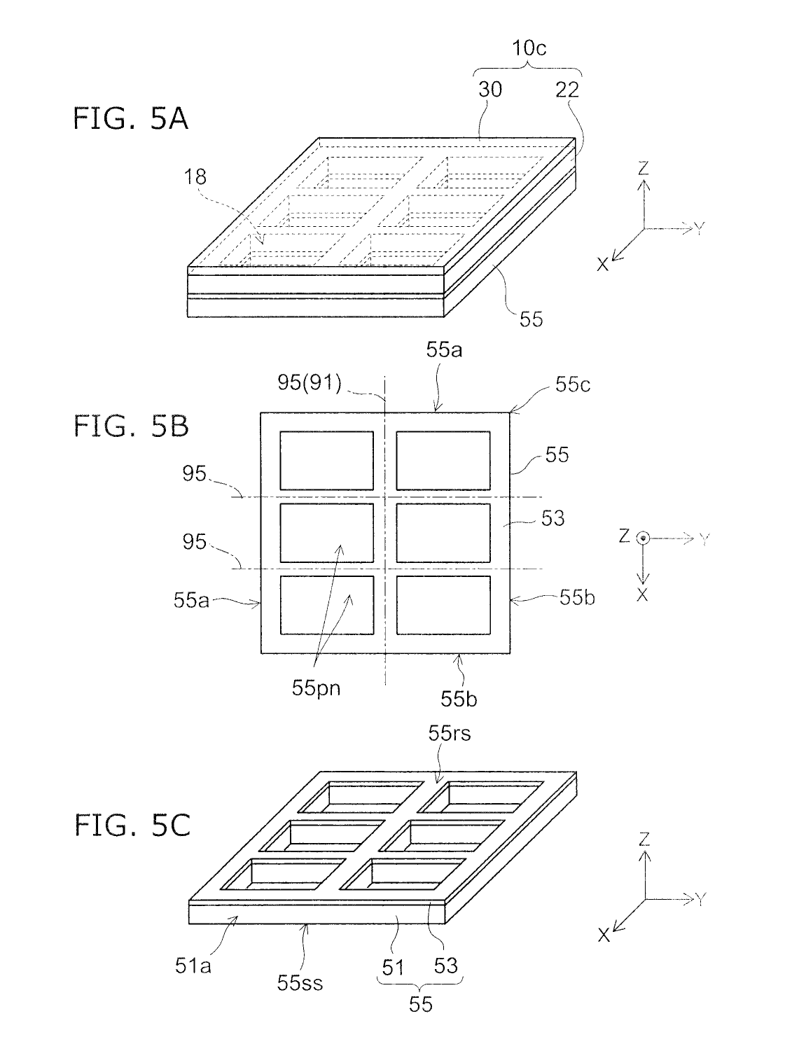

FIG. 5A is a schematic stereo view of an electrostatic chuck according to a second modification example, FIG. 5B is a schematic plan view of a reticle attracted to the electrostatic chuck according to the second modification example, and FIG. 5C is a schematic stereo view of the reticle attracted to the electrostatic chuck according to the second modification example.

FIG. 5A shows an electrostatic chuck 10C and also a reticle 55 attracted to the electrostatic chuck 10C.

As shown in FIG. 5A and FIG. 5B, in a state where the reticle 55 is attracted to an attraction unit 22 of the electrostatic chuck 10C, the attraction unit 22 is located on the outer edge 55c of the rectangle or the square that is the planar external shape of the reticle 55. Further, the attraction unit 22 is located on at least one of second lines 95 connecting between opposing outer edges 55c of the reticle 55.

The reticle 55 has a planar external shape of a rectangle or a square. The reticle 55 has a front surface 55ss on which a pattern is formed, and the reticle 55 has a back surface 55rs that is located on the opposite side to the front surface 55ss and on which a pattern is not formed. A region of the front surface 55ss other than a pattern region 55pn where a pattern is formed is symmetrical with respect to a line (e.g. a center line 91) crossing two opposing sides 55a and 55b of the rectangle or the square.

A conductive layer 53 is provided on the back surface 55rs on the opposite side to a region 51a other than the pattern region 55pn where a pattern is formed. The pattern region 55pn is plurally divided. The region 51a other than the pattern region 55pn corresponds to, for example, a dicing line of a semiconductor wafer. In a state where the reticle 55 is attracted to the attraction unit 22, a space 18 is formed between the reticle 55 and the electrostatic chuck 10C.

### THIRD MODIFICATION EXAMPLE

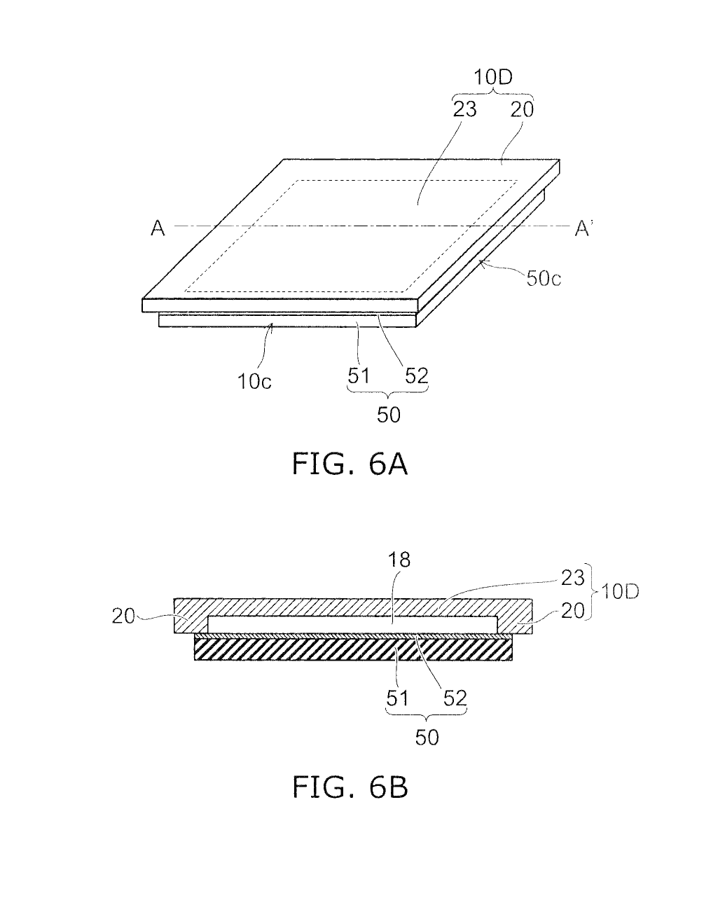

FIG. 6A is a schematic stereo view of an electrostatic chuck according to a third modification example, and FIG. 6B is a schematic cross-sectional view in the position of line A-A′ of FIG. 6A.

FIG. 6A and FIG. 6B show an electrostatic chuck 10D and also the reticle 50 attracted to the electrostatic chuck 10D.

The electrostatic chuck 10D according to the third modification example includes, in addition to the attraction unit 20, an attraction unit 23 (a second attraction unit) capable of attracting the reticle 50 in a non-contact manner by electrostatic attraction force. The attraction unit 23 serves also as a substrate supporting the attraction unit 20.

In a state where the reticle 50 is attracted to the attraction unit 20, the attraction unit 20 is located on the outer edge 50c of the reticle 50, and the attraction unit 23 is located above the reticle 50 other than the outer edge 50c.

### Effects of the Embodiment Will Now be Described

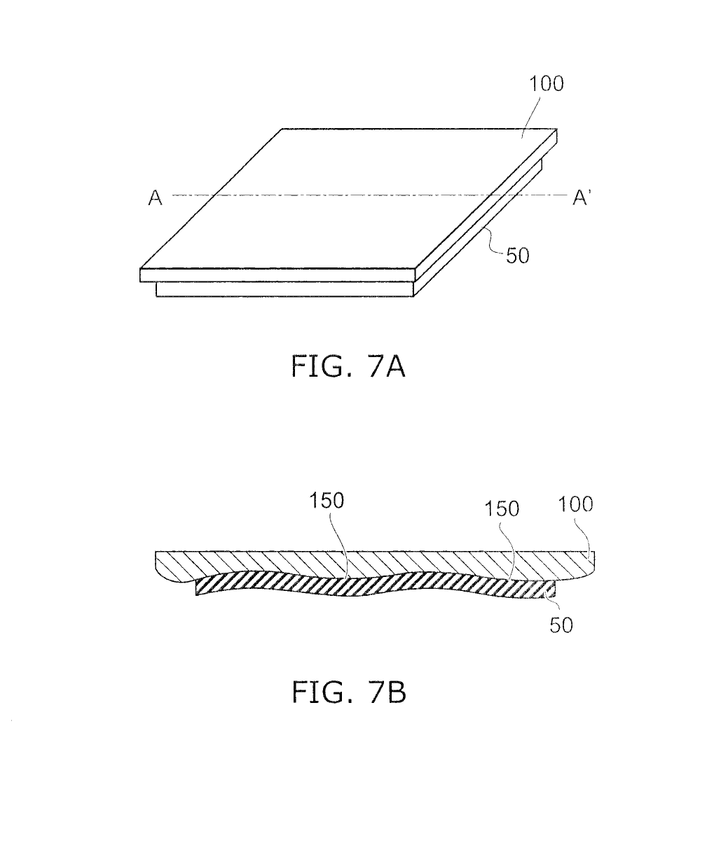

FIG. 7A is a schematic stereo view of an electrostatic chuck according to a reference example, and FIG. 7B is a schematic cross-sectional view in the position of line A-A′ of FIG. 7A.

FIG. 7A and FIG. 7B show an electrostatic chuck 100 and also the reticle 50 attracted to the electrostatic chuck 100.

The electrostatic chuck 100 according to the reference example electrostatically attracts the entire back surface of the reticle 50. When the entire back surface of the reticle 50 is attracted to the electrostatic chuck 100, the reticle 50 may be intricately warped due to the influence of the degree of flatness of the electrostatic chuck 100 and contaminants 150 remaining between the reticle 50 and the electrostatic chuck 100. FIG. 7B shows a state where the reticle 50 is intricately warped.

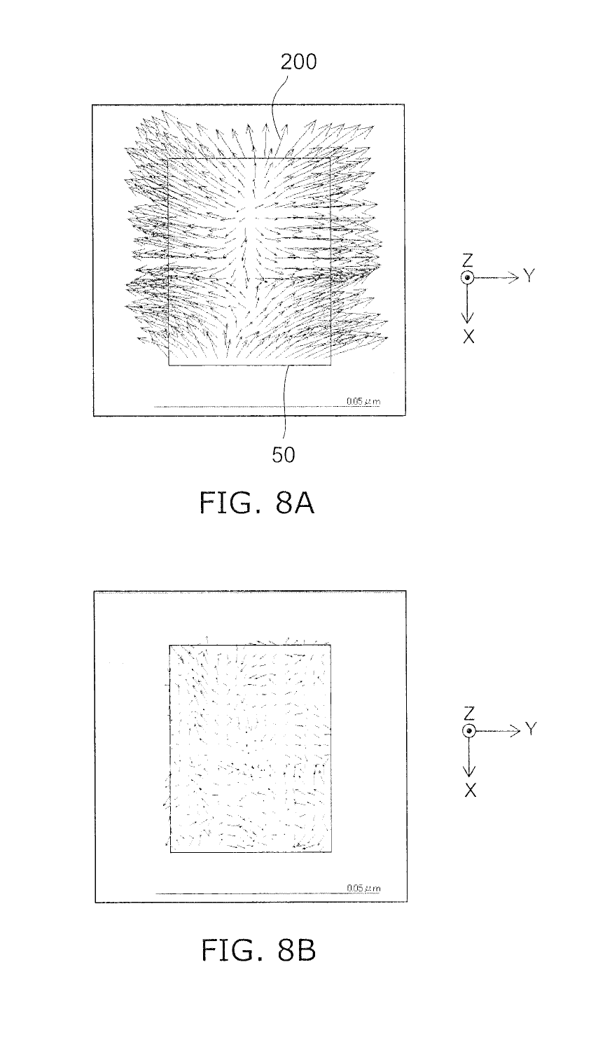

FIG. 8A is a schematic diagram showing shifts of a pattern according to the reference example, and FIG. 8B is a schematic diagram showing a state after the shifts of the pattern according to the reference example are amended by correction.

Arrow 200 in FIG. 8A shows the amount of shift between the pattern of the reticle 50 and the exposure pattern and the direction of the shift. Arrow 200 having a longer length indicates a larger shift amount.

As shown in FIG. 8A, in the case where the electrostatic chuck 100 that eletrostatically attracts the entire back surface of the reticle 50 is used, the directions of the shifts are complicated. For example, the plurality of arrows 200 are directed in the X direction, the −X direction, the Y direction, and the −Y direction and also in directions of combinations of them.

When such a state occurs, some shifts remain as shown in FIG. 8B even after the shifts are optically corrected.

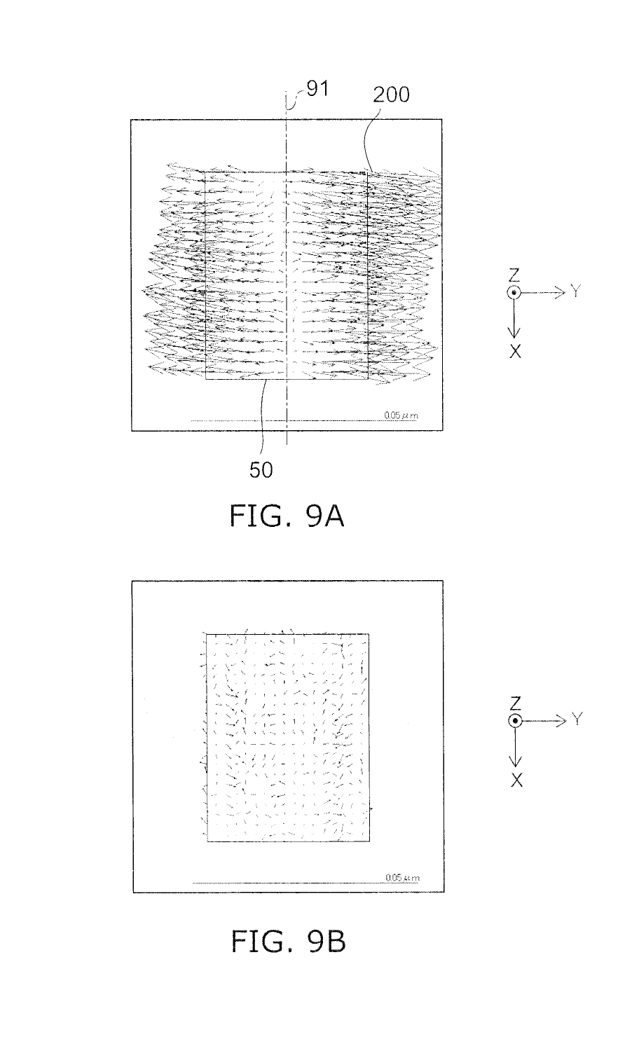

FIG. 9A is a schematic diagram showing shifts of a pattern according to the embodiment, and FIG. 9B is a schematic diagram showing a state after the shifts of the pattern according to the embodiment are amended by correction.

FIG. 9A shows the amount of shift between the pattern of the reticle 50 in the first modification example and the exposure pattern and the direction of the shift.

As shown in FIG. 9A, in the case where the electrostatic chuck 10B that electrostatically attracts both ends of the reticle 50 is used, the directions of the shifts are uniform preferentially in the +Y direction or the −Y direction. This is because when the reticle 50 is lifted by the electrostatic chuck 10B, the reticle 50 warps due to its own weight so that the center line 91 and its vicinity of the reticle 50 are lowest. That is, the reticle 50 warps so that the front surface 50ss side of the reticle 50 is convex.

When such a state occurs, the direction of the shift is preferentially the +Y direction or the −Y direction, and optical shift correction becomes easy. Therefore, the shift after correction is reduced as compared to the reference example (FIG. 9B). That is, the warp of the reticle is suppressed to low frequency components, and the registration accuracy in the shot is improved.

The electrostatic chuck 10A electrically attracts the outer edge of the reticle 50. The structure of the attraction unit 20 of the electrostatic chuck 10A may be considered as a structure of a combination of the attraction unit 21 according to the second modification example and the electrostatic chuck 10B in which the attraction unit 21 is rotated by 180 degrees on the horizontal plane. Thus, in the electrostatic chuck 10A, the direction of the shift is preferentially the +X direction and the −X direction as well as the +Y direction and the −Y direction. Therefore, also in this case, the shift after correction is reduced as compared to the reference example.

The electrostatic chuck 10C attracts, in addition to the outer edge of the reticle 55, the region 51a of the reticle 55 other than the pattern region 55pn where a pattern is formed. Therefore, in the case where the electrostatic chuck 10C is used, the fixability and stability of electrostatic attraction are increased.

The electrostatic chuck 10D not only attracts the outer edge of the reticle 50 by means of the attraction unit 20, but also attracts portions other than the outer edge of the reticle 50 in a non-contact manner by means of the attraction unit 23. Thus, the warp of the reticle 50 due to its own weight is suppressed. Thereby, the shift itself is suppressed, and the shift after correction is further reduced.

In the electrostatic chucks 10A to 10D, when a reticle is attracted, a space 18 is formed between the electrostatic chuck and the reticle. Thus, even when contaminants are attached to the reticle, the contaminants are not caught between the electrostatic chuck and the reticle. Therefore, in the reticle attracted by the electrostatic chuck, bending due to catching contaminants does not occur.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

The term “on” in “a portion A is provided on a portion B” refers to the case where the portion A is provided on the portion B such that the portion A is in contact with the portion B and the case where the portion A is provided above the portion B such that the portion A is not in contact with the portion B.

Furthermore, the components included in the above embodiments can be combined as long as technically feasible. Such combinations are also encompassed within the scope or the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An electrostatic chuck capable of holding a reticle by electrostatic attraction force, the reticle having a planar external shape of a rectangle or a square, the electrostatic chuck comprising:
a first attraction unit capable of attracting the reticle by the electrostatic attraction force; and
a substrate supporting the first attraction unit,
the first attraction unit being symmetrical with respect to a first line when the reticle is attracted to the first attraction unit, the first line crossing two opposing sides of the rectangle or the square.

2. The electrostatic chuck according to claim 1, wherein the first attraction unit is located on an outer edge of the reticle when the reticle is attracted to the first attraction unit.

3. The electrostatic chuck according to claim 1, wherein
the first attraction unit has a first attraction region and a second attraction region and
each of the first attraction region and the second attraction region is located on any of opposing outer edges of the reticle when the reticle is attracted to the first attraction unit.

4. The electrostatic chuck according to claim 1, wherein the first attraction unit is located on the outer edge of the reticle and the first attraction unit is located on at least one of second lines when the reticle is attracted to the first attraction unit, the second lines connect between opposing outer edges of the reticle.

5. The electrostatic chuck according to claim 4, wherein the first attraction unit is located on a region of the reticle, and a pattern is not formed in the region.

6. The electrostatic chuck according to claim 1, further comprising a second attraction unit capable of attracting the reticle in a non-contact manner by the electrostatic attraction force,
the first attraction unit being located on an outer edge of the reticle and the second attraction unit being located above the reticle other than the outer edge when the reticle is attracted to the first attraction unit.

7. A reticle having a planar external shape of a rectangle or a square,
the reticle having a first surface and a second surface, a pattern is formed on the first surface, a pattern is not formed on the second surface, and the second surface is located on an opposite side to the first surface,
a first region of the first surface other than a second region, the pattern is formed on the second region, the first region being symmetrical with respect to a first line, and the first line crossing two opposing sides of the rectangle or the square,
a conductive layer being provided on the second surface on an opposite side to the first region other than the second region.

8. The reticle according to claim 7, wherein the second region is plurally divided.

9. An electrostatic chuck method for holding a reticle by electrostatic attraction force, the reticle having a planar external shape of a rectangle or a square,
the electrostatic chuck including a first attraction unit capable of attracting the reticle by the electrostatic attraction force and a substrate supporting the first attraction unit, the first attraction unit being symmetrical with respect to a first line crossing two opposing sides of the rectangle or the square when the reticle is attracted to the first attraction unit.

10. The method according to claim 9, wherein the first attraction unit is located on an outer edge of the reticle when the reticle is attracted to the first attraction unit.

11. The method according to claim 9, wherein
the first attraction unit has a first attraction region and a second attraction region and
each of the first attraction region and the second attraction region is located individually on any opposing outer edges of the reticle when the reticle is attracted to the first attraction unit.

12. The method according to claim 9, wherein the first attraction unit is located on an outer edge of the reticle and the first attraction unit is located on at least one of second lines when the reticle is attracted to the first attraction unit, the second lines cross opposing outer edges of the reticle.

13. The method according to claim 12, wherein the first attraction unit is located on a region of the reticle, and a pattern is not formed in the region.

14. The method according to claim 12, using the reticle having a planar external shape of a rectangle or a square,
the reticle having a first surface and a second surface, a pattern is formed on the first surface, a pattern is not formed on the second surface, and the second surface is located on an opposite side to the first surface,
a first region of the first surface other than a second region, the pattern is formed on the second region, the first region being symmetrical with respect to a first line, and the first line crossing two opposing sides of the rectangle or the square,
a conductive layer being provided on the second surface on an opposite side to the first region other than the second region.

15. The method according to claim 9, further using a second attraction unit capable of attracting the reticle in a non-contact manner by the electrostatic attraction force,
the first attraction unit being located on an outer edge of the reticle and the second attraction unit being located above the reticle other than the outer edge when the reticle is attracted to the first attraction unit.
